(19) United States
(12) Patent Application Publication
(10) Pub. No.: US 2006/0007975 A1
(43) Pub. Date: Jan. 12, 2006

(54) Laser diode and optical apparatus using it

(75) Inventors: Shoji Hirata, Kanagawa (JP); Daisuke Imanishi, Kanagawa (JP)

Correspondence Address: David R. Metzger;SONNENSCHEIN NATH & ROSENTHAL, Wacker Drive Station, Sears Tower, P.O. Box 061080, Chicago, IL, 60606-1080, US

(73) Assignee: Sony Corporation

(21) Appl. No.: 11/175,561

(22) Filed: Jul. 6, 2005

(30) Foreign Application Priority Data
Jul. 12, 2004 (JP) P2004-205240

(51) Int. Cl. H01S 5/00

(52) U.S. Cl. 372/45.011; 372/45.01

(57) ABSTRACT

A laser diode capable of inhibiting overflow of electrons in a p-type cladding layer and improving temperature characteristics and light emitting efficiency is provided. A laser diode at least comprises: an n-type cladding layer; an active layer; and a p-type cladding layer, which are made of an AlGaInP compound semiconductor material and formed in this order on a substrate. A thickness of the p-type cladding layer is 0.7 μm or less.

### CROSS REFERENCES TO RELATED APPLICATIONS

The present invention contains subject matter related to Japanese Patent Application JP 2004-205240 filed in the Japanese Patent Office on Jul. 12, 2004, the entire contents of which being incorporated herein by reference.

### BACKGROUND OF THE INVENTION

1. Field of the Invention

The present invention relates to a laser diode made of an AlGaInP (aluminum, gallium, indium, and phosphorus) compound semiconductor material, and an optical apparatus using it such as an optical recording and reproducing apparatus and a display apparatus.

2. Description of the Related Art

Laser diodes emit light by electron-hole recombination in the active layer. However, in some cases, depending on component materials for laser diodes, carrier overflow phenomenon that electrons and holes, which should remain for generating recombination in the active layer flow over from the active layer is shown. Such increase in carrier overflow means decrease in light emitting efficiency. Easiness of carrier overflow (intensity of confining electrons or holes to the active layer) is determined by the size of the conduction band barrier, that is, the size of a difference between the pseudo fermi level of the active layer and the fermi level of the cladding layer ΔEc (for example, refer to M. Kondow and five authors., “GaInNAs: A novel material for long-wavelength-range laser diodes with excellent high-temperature performance,” Japanese Journal of Applied Physics, February 1996, Vol. 35-1-2B, pp. 1273-1275).

In general, in the laser diode using an AlGaAs (aluminum, gallium, and arsenic) material, which emits light having a wavelength of about 800 nm, or in the laser diode using a GaN (gallium nitride) material, which emits light having a wavelength of about 400 nm, the conduction band barrier is sufficiently large. Therefore, stable high temperature and high output operation can be obtained. Specifically, in the W class high output laser of 808 nm infrared range formed by using the AlGaAs material, about 50% light emitting efficiency has been obtained.

However, in the red laser diode formed in a double hetero structure by using an InGaAsP material, as shown in FIG. 1, in order to obtain the oscillation wavelength shorter than 640 nm, the band gap of the active layer should be large. Thereby, there has been a disadvantage that the conduction band barrier becomes small, carrier overflow is increased, and reliability of the operation is decreased at the temperatures over 60 deg C.

Such decrease in temperature characteristics is peculiar to the laser diode fabricated by using an AlGaInP material, in which only about 20% light emitting efficiency has been obtained at maximum. Further, when characteristics temperatures of 200 mW class laser diodes for writing optical disk are compared, the characteristics temperature of the laser diode for CD-R (Compact Disc Recordable) is about 150 K, while the characteristics temperature of the laser diode for writing DVD (Digital Versatile Disk) is only 100 K. In particular, since red laser is widely used as a consumer laser, it is strongly desired that the red laser can be stably used in a wide temperature range.

In order to improve temperature characteristics, various efforts have been made heretofore. Of the efforts, an action to prevent heat generation from the p-type cladding layer and carrier overflow due to heat generation by increasing an impurity concentration while preventing the impurity contained in the p-type cladding layer from being diffused and entering into the active layer has been examined. For such an action, for example, the following methods have been used. That is, a method, in which, in the AlGaInP laser diode, on an n-type GaAs substrate, an n-type (Alₓ₁Ga₁₋ₓ₁)_{1-y1}In_{y1}P cladding layer having lattice mismatch from 2.0× ⁻⁴ to 3.0×10 ⁻³ to the n-type GaAs substrate; an (Alₓ₂Ga₁₋ₓ₂)_{1-y2}In_{y2}P light guiding layer; an MQW (Multi Quantum Well) structured active layer including a Ga_{1-z}In_{z}P quantum well layer and an (Alₓ₂Ga₁₋ₓ₂)_{1-y2}In_{y2}P barrier layer; an (Mₓ₂Ga₁₋ₓ₂)_{1-y2}In_{y2}P light guiding layer; and a p-type (Alₓ₁Ga₁₋ₓ₁)_{1-y1}In_{y1}P cladding layer are sequentially layered (for example, refer to Japanese Unexamined Patent Application Publication No. H11-87831) has been used. Another example method for such an action is a method, in which a layer which has the larger lattice constant than of the substrate, includes +strain, and contains no zinc which is the impurity is provided between the active layer and a layer containing zinc (for example, refer to Japanese Unexamined Patent Application Publication No. 2004-47962).

### SUMMARY OF THE INVENTION

As described above, in the past, various efforts have been made in order to improve temperature characteristics. However, when the method disclosed in Japanese Unexamined Patent Application Publication No. H11-87831 is used, in order to obtain a high output red laser, it is necessary to further increase the amount of the impurity doped into the p-type cladding layer to inhibit heat generation. Further, when the method disclosed in Japanese Unexamined Patent Application Publication No. 2004-47962 is used, in addition to the step of forming the layer containing the impurity (zinc), the step of forming the layer containing no impurity (zinc) should be further provided, leading to shortcomings such as increase in load in view of manufacturing processes.

In view of such disadvantages, in the present invention, it is desirable to provide a laser diode capable of inhibiting carrier overflow phenomenon in the p-type cladding layer and improving temperature characteristics, and an optical apparatus using it.

According to an embodiment of the present invention, there is provided a first laser diode at least including an n-type cladding layer, an active layer, and a p-type cladding layer, which are made of an AlGaInP compound semiconductor material and formed in this order on a substrate, in which the thickness of the p-type cladding layer is 0.7 ηm or less.

Here, the p-type cladding layer has +strain (compressive strain). The average crystal lattice mismatch degree Δa/a to the substrate is preferably +3×10⁻³ or more (Δa represents a difference between a crystal lattice constant of the p-type cladding layer and a crystal lattice constant of the substrate; and a represents a crystal lattice constant of the substrate). Further, the concentration of p-type impurity (for example, zinc) in the p-type cladding layer is preferably 2×10¹⁸/cm³ to 3×10¹⁸/cm³.

According to an embodiment of the present invention, there is provided a second laser diode at least including an n-type cladding layer, an active layer, and a p-type cladding layer, which are made of an AlGaInP compound semiconductor material and formed in this order on a substrate, in which the thickness of the p-type cladding layer is 0.7 μm or less, the stripe width in a light emitting region in the active layer is 10 μm or more, and the resonator length is 700 μm or more.

According to an embodiment of the present invention, there is provided an optical apparatus including the first or the second laser diode.

In the first laser diode according to the embodiment of the present invention, the thickness of the p-type cladding layer is thin, being 0.7 μm or less. Therefore, compared to the related art, the serial resistance and the exhaust heat resistance are reduced by the decrease in the layer thickness. Further, the average crystal lattice mismatch degree Δa/a can be more than +3×10⁻³ dynamically. As above, since the average crystal lattice mismatch degree in the p-type cladding layer is increased, the doping amount of zinc as p-type impurity can be increased to the range from 2×10¹⁸/cm³ to 3×10¹⁸/cm³. In addition, doped zinc is activated and zinc is prevented from being diffused into the active layer, so that the active layer can be prevented from becoming a non-light emitting center. As above, by increasing the doping amount of zinc, that is, by increasing the carrier concentration in the p-type cladding layer, the serial resistance is further decreased, and the fermi level of the p-type cladding layer becomes sloped. Since the fermi level of the p-type cladding layer becomes sloped, the band gap of the p-type cladding layer is not increased even if the effective value of the fermi level is increased. Therefore, it is not necessary to apply a high drive voltage Vₒₚ. By these actions, heat generation is inhibited, and generation of leak current by overflow of electrons is inhibited.

In the second laser diode according to the embodiment of the present invention, the n-type cladding layer, the active layer, and the p-type cladding layer, which are made of an AlGaInP compound semiconductor material are included in this order on the substrate. The thickness of the p-type cladding layer is 0.7 μm or less, the stripe width in a light emitting region in the active layer is 10 μm or more, and the resonator length is 700 μm or more. Therefore, high output is obtained and heat generation is inhibited. Further, generation of leak current by overflow of electrons is inhibited.

The optical apparatus according to the embodiment of the present invention includes the foregoing first or the second laser diode. Therefore, temperature characteristics are improved.

According to the first laser diode of the embodiment of the present invention, the thickness of the p-type cladding layer made of the AlGaInP compound semiconductor material is thin, being 0.7 μm or less. Therefore, the serial resistance and the exhaust heat resistance are decreased, and temperature rise can be inhibited. In addition, overflow of electrons in the p-type cladding layer can be inhibited. As a result, temperature characteristics and light emitting efficiency are improved, and reliability is improved.

In particular, by introducing +strain to the p-type cladding layer, and setting the average crystal lattice mismatch degree Δa/a with respect to the substrate to +3×10⁻³ or more, the doping amount of zinc as p-type impurity can be increased to the range from 2×10¹⁸/cm³ to 3×10¹⁸/cm³. In addition, doped zinc is activated and zinc is prevented from being diffused into the active layer, so that the active layer is inhibited from becoming a non-light emitting center.

Further, since the doping amount of zinc is increased to the range from 2×10¹⁸/cm³ to 3×10¹⁸/cm³, the carrier concentration in the p-type cladding layer is increased and the serial resistance can be further decreased, and at the same time, the fermi level of the p-type cladding layer can be sloped. Therefore, the effective value of the fermi level can be increased without increasing the band gap of the p-type cladding layer, and therefore it is not necessary to apply a high drive voltage. Consequently heat generation is inhibited, and generation of leak current by overflow of electrons can be inhibited.

Further, according to the second laser diode of the embodiment of the present invention, the thickness of the p-type cladding layer is 0.7 μm or less, the stripe width in the light emitting region in the active layer is 10 μm or more, and the resonator length is 700 μm or more. Therefore, high output is enabled, the serial resistance and the exhaust heat resistance are decreased, and temperature rise can be inhibited. In addition, overflow of electrons in the p-type cladding layer can be inhibited. Therefore, temperature characteristics and light emitting efficiency are improved, and reliability is improved.

In particular, in the case of the resonator length from 700 μm to 1000 μm, when the end face reflectance of the light emitting region on the light extraction side is 10% to 30%, and the end face reflectance of the light emitting region on the other side of the light extraction side is 90% or more, higher effects can be obtained.

Further, in the case of the resonator length of 1000 μm or more, when the end face reflectance of the light emitting region on the light extraction side is 2% to 15%, and the end face reflectance of the light emitting region on the other side of the light extraction side is 90% or more, higher effects can be obtained.

Further, when the relation between the confinement factor Γ of the light mode (light guiding mode) guided in the active layer and the thickness d of the active layer is d/Γ≦0.3 μm, higher effects can be obtained.

According to the optical apparatus of the embodiment of the present invention, the first or the second laser diode according to the respective embodiments of the present invention is included. Therefore, temperature characteristics are improved and stable usage is enabled in a wide temperature range. In addition, output wavelength becomes stable, and reliability or color reproducibility is improved.

Other and further objects, features and advantages of the invention will appear more fully from the following description.

### BRIEF DESCRIPTION OF THE DRAWINGS

FIG. 1 is a band view of a traditional laser diode;

FIG. 2 is a perspective view showing a construction of a laser diode according to a first embodiment of the present invention;

FIG. 3 is a view showing light guiding mode in the lamination direction of the laser diode;

FIG. 4 is a band view of the laser diode;

FIG. 5 is a cross section showing a construction in the resonator length direction of the laser diode;

FIG. 6 is a cross section showing a construction in the resonator length direction of a laser diode according to a second embodiment of the present invention;

FIG. 7 is a view showing a fundamental vertical structure of the laser diode in obtaining a guiding mode;

FIG. 8 is an example of a view showing characteristics temperatures of the laser diode;

FIG. 9 is an example of a view showing light emitting efficiency of the laser diode;

FIG. 10 is an example of a view showing light emitting outputs of the laser diode;

FIG. 11 is an example of a view showing characteristics temperatures of the laser diode;

FIG. 12 is an example of a view showing light emitting efficiency of the laser diode;

FIG. 13 is an example of a view showing light emitting outputs of the laser diode;

FIG. 14 is an example of a view showing light emitting efficiency of the laser diode;

FIG. 15 is an example of a view showing characteristics temperatures of the laser diode;

FIG. 16 is an example of a view showing light emitting efficiency of the laser diode;

FIG. 17 is an example of a view showing characteristics temperatures of the laser diode;

FIG. 18 is an example of a view showing characteristics temperatures of the laser diode;

FIG. 19 is an example of a view showing light emitting efficiency of the laser diode;

FIG. 20 is an example of a view showing light emitting outputs of the laser diode;

FIG. 21 is a view showing an example of a configuration of an optical apparatus including the laser diode shown in FIG. 2 or FIG. 6;

FIG. 22 is a view showing an example of a configuration of other optical apparatus including the laser diode shown in FIG. 2 or FIG. 6; and

FIG. 23 is a cross section showing a modification of the laser diode shown in FIG. 2 or FIG. 6.

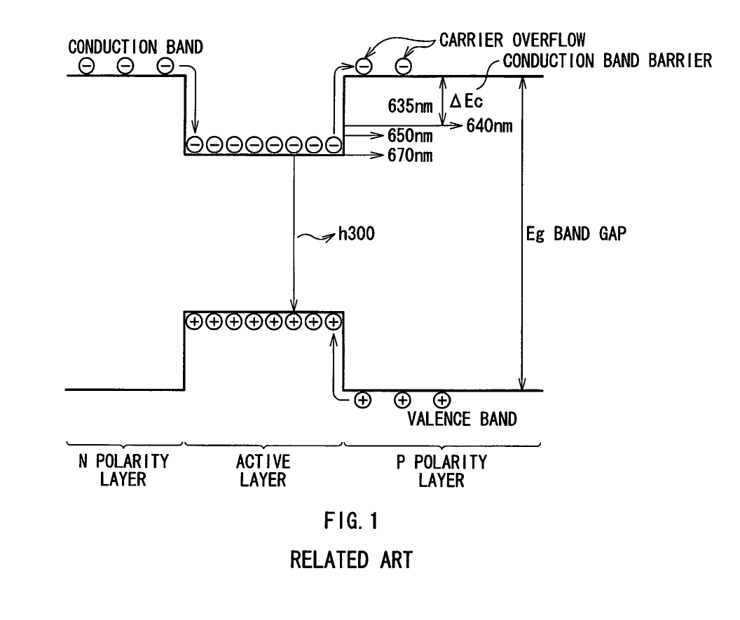

### DETAILED DESCRIPTION OF THE PREFERRED EMBODIMENTS

Descriptions will be given of embodiments of the present invention in detail with reference to the drawings.

### First Embodiment

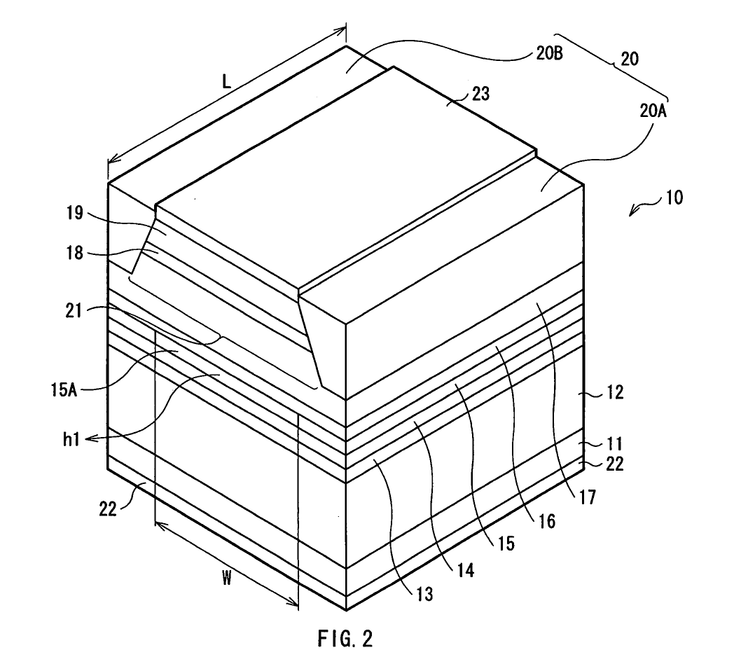

FIG. 2 shows a structure of a laser diode according to a first embodiment of the present invention. In a laser diode 10, for example, on one face side of a substrate 11, an n-type cladding layer 12, a first n-type guiding layer 13, a second n-type guiding layer 14, an active layer 15, a p-type guiding layer 16, a p-type cladding layer 17, an intermediate layer 18, and a p-side contact layer 19 are layered in this order. A buried layer 20 is formed in a region including the p-type cladding layer 17, the intermediate layer 18, and the p-side contact layer 19.

The substrate 11 has, for example, a thickness in the lamination direction of 100 μm (hereinafter simply referred to as thickness). The substrate 11 is made of n-type GaAs doped with n-type impurity such as silicon (Si) and selenium (Se).

The n-type cladding layer 12 has, for example, a thickness of 0.8 μm, and is made of an n-type AlInP mixed crystal doped with n-type impurity such as silicon and selenium. The thickness of the n-type cladding layer 12 is thin, being 0.8 μm thick, as of the after-mentioned p-type cladding layer 17. However, the thickness of the n-type cladding layer 12 may be 1.0 μm or more. The n-type cladding layer 12 does not much contribute to increase in the serial resistance component. Further, in view of exhaust heat, since the n-type cladding layer 12 is far from a heat sink, the thickness of the n-type cladding layer 12 does not much become a matter. However, in view of reducing manufacturing time, it is not necessary to thicken the n-type cladding layer 12 more than needs.

The first n-type guiding layer 13 and the second n-type guiding layer 14 have, for example, a thickness of 100 nm, respectively. The first n-type guiding layer 13 is made of an Al_{0.5}Ga_{0.5}InP mixed crystal. The second n-type guiding layer 14 is made of an Al_{0.6}Ga_{0.4}InP mixed crystal. The first n-type guiding layer 13 and the second n-type guiding layer 14 do not have to contain impurity, or may be doped with n-type impurity such as silicon and selenium.

The active layer 15 has, for example, a thickness of 12 nm, and is made of a GaInP mixed crystal. The composition of indium contained in the active layer 15 is, for example, preferably about 0.5, since thereby lattice match with GaAs of the component of the substrate 11 can be made.

The p-type guiding layer 16 has, for example, a thickness of 100 nm, and is made of an Al_{0.6}Ga_{0.4}InP mixed crystal. The p-type guiding layer 16 does not have to contain impurity, or may be doped with p-type impurity such as zinc (Zn) and magnesium (Mg).

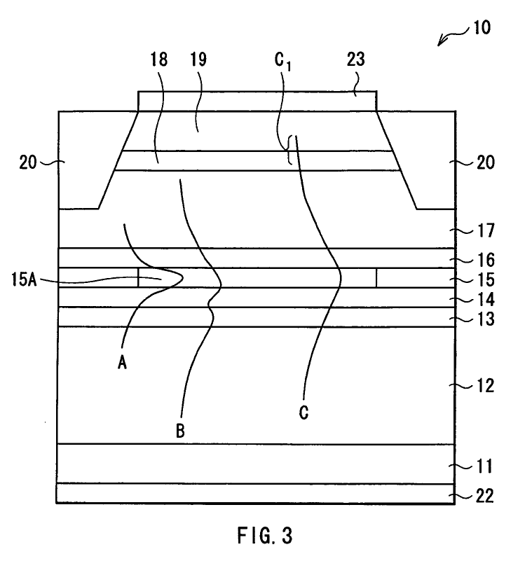

Further, as shown in FIG. 3, in this embodiment, it is possible that the first n-type guiding layer 13 and the second n-type guiding layer 14, and the p-type guiding layer 16 have asymmetric thicknesses centering on the active layer 15, and thereby light guiding mode can be widened, that is, a value of a confinement factor Γ can be decreased (B in FIG. 3). The reason thereof is as follows. In particular, in the case of a high output laser, when the cladding layers (12, 17) are thinned to confine light in the narrow range, and light is concentrated on the active layer 15 (A in FIG. 3), the materials forming the cladding layers (12, 17) and the active layer 15 become deteriorated. Further, in this embodiment, the thickness of the n-side guiding layer is thickened, or the number of the n-side guiding layers is increased, or the refractive index of the n-side guiding layer is increased. Thereby, the light guiding mode is drawn to the n-side (B in FIG. 3). The reason thereof is that even when the after-mentioned thin p-type cladding layer 17 is used, light leak to the p-side contact layer 19 or the like (C₁ section of C in FIG. 3) can be thereby inhibited, and the light guiding mode can be thereby sufficiently confined.

Further, in this embodiment, the first and the second n-side guiding layers are layered to draw the light guiding mode to the n side. However, by considering the balance between light loss by dispersion of optical intensity and light loss by light leak to the p-side contact layer 19, it is possible to provide an additional n-type guiding layer according to needs.

The p-type cladding layer 17 according to this embodiment has, for example, a thickness of 0.6 μm, and is made of a p-type AlInP mixed crystal doped with p-type impurity such as zinc and magnesium. In this embodiment, the case using zinc as p-type impurity is described. Traditionally, the general thickness of the p-type cladding layer is about 1.5 μm. However, as described above, by making the thickness of the p-type cladding layer 17 half or less of the traditional thickness, specifically 0.7 μm or less, a serial resistance R₈ of the p-type cladding layer 17 is decreased by such decreased portion of the thickness, and the heat value corresponding to such decreased portion of the serial resistance Rₛ(ΔRₛ×(Iₒₚ)², where Iₒₚ is a drive current) can be decreased. Further, an exhaust heat resistance Rₜₕ can be also decreased, and generated heat can be effectively released. By such synergy effect, temperature rise of the driven laser diode can be inhibited. Further, the thickness of the p-type cladding layer 17 is preferably 0.4 μm or more. When the thickness of the p-type cladding layer 17 is 0.4 μm or less, sufficient light confinement is not enabled, light absorption loss in the p-side contact layer 19 is increased, and in the result, the threshold current of the laser diode is increased.

Further, an average crystal lattice mismatch degree Δa/a of the p-type cladding layer 17 to the substrate 11 is +3×10⁻³ or more (where Δa represents a difference between the crystal lattice constant of the p-type cladding layer and the crystal lattice constant of the substrate, and a represents a crystal lattice constant of the substrate). As described above, the thickness of the traditional p-type cladding layer is thick, being 1.5 μm or more, and therefore introducing +strain to the p-type cladding layer has been dynamically difficult (the critical film thickness would be surpassed). Therefore, traditionally, the average crystal lattice mismatch in the p-type cladding layer has remained at about 3.0×10⁻³ or less (refer to Japanese Unexamined Patent Application Publication No. H11-87831). However, in this embodiment, the thickness of the p-type cladding layer 17 is formed very thin, being 0.7 μm or less. Thereby, it is possible to introduce more +strain to the p-type cladding layer 17. Though the allowable value of Δa/a depends on the thickness of the p-type cladding layer 17, Δa/a is preferably +1×10⁻² or less. When the value of Δa/a is +1×10⁻² or more, the thickness of the p-type cladding layer 17 surpasses the critical film thickness, and it is difficult to maintain good crystallinity.

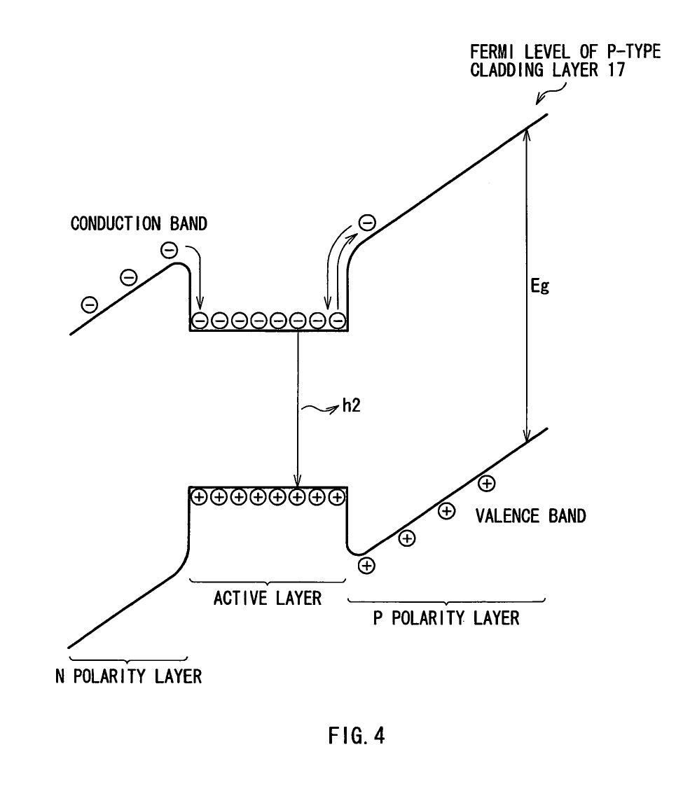

Further, the doping amount of zinc as the p-type impurity in the p-type cladding layer 17 is 2×10¹⁸/cm³ to 3×10¹⁸/cm³, which is higher than ever before (about 7×10¹⁷). Thereby, as shown in FIG. 4, the fermi level of the p-type cladding layer 17 can be sloped, generation of a leak current by overflow of electrons can be inhibited, and the effective value of the fermi level of the p-type cladding layer 17 can be increased without increasing a band gap (E_{g}) of the p-type cladding layer 17. Therefore, it is not necessary to increase a drive voltage Vₒₚ, and heat generation can be inhibited.

In general, in many cases, when lots of impurity is doped as above, zinc becomes inactivated in the crystal of the p-type cladding layer 17 and easily diffused. Then, when the inactivated zinc is diffused into the active layer 15, it is often that the active layer 15 becomes a non-light emitting center, and reliability of the device is lost. However, in this embodiment, as described above, the average crystal lattice mismatch degree is increased. Therefore, the doing amount of zinc (p doping amount) can be increased, carrier in the p-type cladding layer 17 is increased, and serial resistance Rₛ of the p-type cladding layer 17 is decreased to inhibit heat generation. In addition, doped zinc is activated, and diffusion of zinc is inhibited.

The intermediate layer 18 smoothly mediates band gap change between the p-side contact layer 19 and the p-type cladding layer 17 to facilitate hole injection. The intermediate layer 18 has, for example, a thickness of 30 nm, and is made of p-type GaInP doped with p-type impurity such as zinc and magnesium.

The p-side contact layer 19 has, for example, a thickness of 0.2 μm, and is made of p-type GaAs doped with p-type impurity such as zinc and magnesium.

Of the foregoing, a section sandwiched between two buried layers 20A and 20B in the p-type cladding layer 17, the intermediate layer 18 and the p-side contact layer 19 are a narrow strip-shaped (in FIG. 2, strip shape extending in the direction perpendicular to the paper plane) ridge 21. The ridge 21 limits the current injection region of the active layer 15. The portion of the active layer 15 corresponding to the ridge 21 is the current injection region.

The buried layer 20 formed on the top face of the p-side contact layer 19 is opened to form a p-side electrode 23. Thereby, the p-side contact layer 19 and the p-side electrode 23 are electrically connected. The p-side electrode 23 has a structure, in which, for example, titanium (Ti), platinum (Pt), and gold (At) are sequentially layered. On the rear side of the substrate 11, an n-side electrode 22 is formed. The n-side electrode 22 has a structure, in which, for example, AuGe:Ni and gold (Au) are sequentially layered, which is alloyed by heat treatment and is electrically connected to the substrate 11.

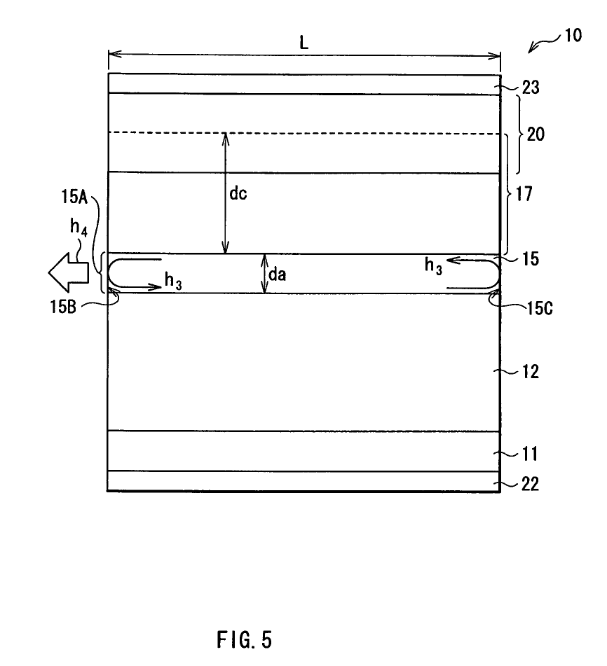

Further, as shown in FIG. 5, in the laser diode 10, a pair of side faces opposed to each other in the resonator direction is resonator end faces (15B and 15C). On the resonator end faces (15B and 15C), a reflector film (not shown) is respectively formed. Of the pair of reflector films, a front end face (light extraction side) reflectance R_{f} is adjusted to low reflectance, and a rear end face reflectance Rᵣ is adjusted to high reflectance. Thereby, light h₃ generated in the active layer 15 travels (resonates) between the pair of resonator end faces (15B and 15C) and amplified, and emitted as a laser beam (emitted light) h₄ from a light emitting region 15A on the low reflectance side.

In the laser diode 10 according to this embodiment, in the case of the narrow stripe laser maintaining single mode by adjusting a stripe width W of the light emitting region 15A to about 2 μm, 200 mW to 300 mW class output becomes enabled. Such laser can be utilized, for example, as a writing laser for DVD.

The laser diode 10 can be manufactured as follows.

First, for example, on the surface of the substrate 11 made of the foregoing material having the foregoing thickness, for example, by MOCVD (Metal Organic Chemical Vapor Deposition) method, the n-type cladding layer 12, the first n-type guiding layer 13, the second n-type guiding layer 14, the active layer 15, the p-type guiding layer 16, the p-type cladding layer 17, the intermediate layer 18, and the p-side contact layer 19, which are respectively made of the foregoing material and have the foregoing thickness are sequentially layered. Then, the p-type cladding layer 17 is formed so that the layer thickness becomes 0.7 μm or less by using an (AlₓGa₁₋ₓ)_{1-y}In_{y}P (0≦x<1, 0<y<1) mixed crystal, in which the composition ratio of indium is adjusted so that the average crystal lattice mismatch degree becomes Δa/a>+3×10⁻³, and further doping with zinc of the p-type impurity in the range from 2×10¹⁸/cm³ to 3×10¹⁸/cm³.

Here, the composition ratio of indium in the (AlₓGa₁₋ₓ)_{1-y}In_{y}P mixed crystal of the material forming the p-type cladding layer 17 is obtained by the formula expressed as y=(5.654×Δa/a+0.10556)/0.21736. For example, in the case that the average crystal lattice mismatch degree (Δa/a) is +3×10⁻³, the composition ratio of indium shall be 56.37% (y=0.5637). The composition of indium becomes higher by about 7.8%, compared to the case of the conditions of lattice match to GaAs, in which y is 0.4856.

After that, etching is performed, and part of the p-type cladding layer 17, the intermediate layer 18, and the p-side contact layer 19 is selectively removed to obtain the narrow strip-shaped ridge 21. After the ridge 21 is formed, on the both sides thereof and on the p-side contact layer 19, the buried layer 20 is formed by layering the foregoing material by, for example, CVC (Chemical Vapor Deposition) method.

After the buried layer 20 is formed, for example, the rear side of the substrate 11 is ground to make the thickness of the substrate 11 about 100 μm, and the n-side electrode 22 is formed on the rear side of the substrate 11. Further, the buried layer 20 is provided with an aperture corresponding to the p-side contact layer 19 by, for example, etching, and the p-side electrode 23 is formed on the p-side contact layer 19. After the n-side electrode 22 and the p-side electrode 23 are formed, the substrate 11 is adjusted to a given size and an unshown reflector film is formed on the pair of resonator end faces opposed to each other in the long direction of the p-side contact layer 19. Thereby, the laser diode 10 shown in FIG. 2 is formed.

In such laser diode 10, when a given voltage is applied between the n-side electrode 22 and the p-side electrode 23, current confinement is made by the ridge 21, a current is injected into the active layer 15, and light emitting is generated by electron-hole recombination. The light is reflected by the unshown pair of reflector films, travels between them, generates laser oscillation, and is emitted outside as a laser beam.

Here, the thickness of the p-side cladding layer 17 is thinner than ever before, being 0.7 μm or less. Therefore, the serial resistance Rₛ and the exhaust heat resistance Rₜₕ are decreased by the decreased portion of the thickness. Further, dynamically, the average crystal lattice mismatch degree (Δa/a) can be more than +3×10⁻³. As above, when the average crystal lattice mismatch degree in the p-type cladding layer 17 is increased, zinc as the p-type impurity is activated, so that zinc is not diffused into the active layer 15, and the active layer 15 does not become a non-light emitting center. Further, it becomes possible to increase the doping amount of zinc to the range from 2×10¹⁸/cm³ to 3×10¹⁸/cm³. By increase in the doping amount of zinc, the carrier concentration in the p-type cladding layer 17 is increased, the serial resistance Rₛ is further decreased, and the fermi level of the p-type cladding layer 17 can be sloped. Then, since the fermi level of the p-type cladding layer 17 is sloped, the band gap (E_{g}) of the p-type cladding layer 17 is not increased even if the effective value of the fermi level is increased. Therefore, it is not necessary to increase the drive voltage Vₒₚ. As a result, heat generation is inhibited, and generation of leak current due to overflow of electrons is inhibited. Thereby, temperature characteristics and light emitting efficiency are improved, and reliability is improved.

As above, in the laser diode 10 of this embodiment, the p-type cladding layer 17 is formed thinner than ever before, being 0.7 μm or less. Therefore, the serial resistance Rₛ and the exhaust heat resistance Rₜₕ are reduced, and thereby temperature rise can be inhibited. Further, overflow of electrons in the p-type cladding layer 17 and the like can be inhibited. Therefore, temperature characteristics can be improved, and reliability can be improved.

In particular, when the average crystal lattice mismatch degree (Δa/a) in the p-type cladding layer 17 is more than +3×10⁻³, doped zinc is activated, so that zinc is inhibited from being diffused into the active layer 15. Therefore, the active layer 15 is inhibited from becoming a non-light emitting center. Further, it becomes possible to increase the doping amount of zinc to the range from 2×10¹⁸/cm³ to 3×10¹⁸/cm³.

Further, in this embodiment, since the doping amount of zinc can be increased to the range from 2×10¹⁸/cm³ to 3×10¹⁸/cm³, the carrier (zinc) concentration in the p-type cladding layer 17 can be increased, the serial resistance Rₛ can be further decreased, and the fermi level of the p-type cladding layer 17 can be sloped.

Since the fermi level of the p-type cladding layer 17 is sloped as above, the band gap (E_{g}) of the p-type cladding layer 17 is not increased even if the effective value of the fermi level is increased. Therefore, it is not necessary to apply a high drive voltage Vₒₚ. As a result, heat generation is inhibited, and generation of leak current due to overflow of electrons can be inhibited. Thereby, temperature characteristics and light emitting efficiency can be improved, and reliability can be improved.

In addition, it is preferable to perform exhaust heat for the laser diode 10 by using a sub-mount and a heat sink. Then, by mounting the sub-mount and the heat sink on the p polarity side of the laser diode 10 (p side down), higher exhaust heat effects can be obtained. In this case, heat can be exhausted without through the thick substrate layer on the n polarity side.

Descriptions will be hereinafter given of other embodiment of the present invention. In the description of the following embodiment, the same components as of the first embodiment will be given the same symbols, and detailed descriptions thereof will be omitted.

### Second Embodiment

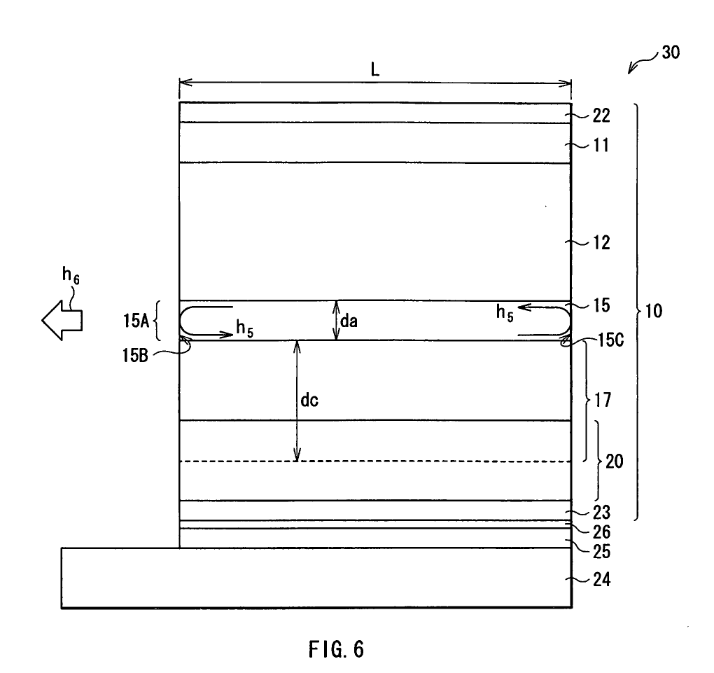

The laser diode 10 according to a second embodiment shown in FIG. 6 has the same construction as of the laser diode 10 according to the first embodiment, except that the stripe width W is 10 μm or more, and a heat sink 24, a sub-mount 25, a solder layer 26, and the p-side electrode 23 are welded and mounted in this order by placing the p polarity side of the laser diode 10 on the bottom side. Since the stripe width W is formed 10 μm or more, the laser diode 10 can output 300 mW or more. The laser diode 10 can be utilized as a high output laser for optical disk apparatuses, display apparatuses, laser equipment for process, medical equipment, printing and the like.

Further, corresponding to the stripe width W and a resonator length L, appropriate ranges of the front end face reflectance R_{f} of the front end face 15B on the light extraction side and the rear end face reflectance Rᵣ of the rear end face 15C; and a relation between a confinement factor Γ of the light guiding mode in the active layer 15 and a thickness dₐ of the active layer 15 (dₐ/Γ) are respectively specified. Thereby, temperature characteristics and light emitting effects can be improved, and reliability can be also improved. Then, the stripe width W, the resonator length L, the front end face reflectance R_{f}, and the rear end face reflectance Rᵣ were calculated by the following calculation method. Main parameters are shown as follows. Tₒ represents a characteristics temperature, Jₒ represents a clearing current density, dₐ represents the thickness of the active layer, d_{c} represents a thickness of the p-type cladding layer, Rₜₕ represents the exhaust heat resistance, P_{f} represents a front light output, and T_{c} represents a heat sink temperature.

First, a threshold current density Jₜₕ is obtained by Mathematical formula 1, where ηᵢ is an internal quantum efficiency, αᵢ is a guiding loss, Γ is the confinement factor to the active layer, J_{I} is a leak current density, and β is a gain factor (proportional coefficient of the current density and the obtained gain). In the case of a red material, the value of β is about 2.3×10⁻² cm·μm/A.

$${J}_{th} = \frac{d}{{η}_{i} Γβ} \{ {α}_{i} + \frac{1}{2 L} ln ( \frac{1}{{R}_{f} \cdot {R}_{r}} ) + \frac{{J}_{o} \cdot d}{{η}_{i}} + {J}_{l} \qquad [ Mathematical formula 1 ]$$

Subsequently, a threshold value Iₜₕ is obtained by multiplying Jₜₕ by the area of the active layer as Mathematical formula 2, and an external differential efficiency is obtained as Mathematical formula 3:

[Mathematical formula 2]
Iₜₕ=JₜₕLW

$${η}_{d} = \frac{1.24 {η}_{i}}{λ} ( \frac{{α}_{m}}{{α}_{i} + {α}_{m}} ) \qquad [ Mathematical formula 3 ]$$

where αₘ is expressed as Mathematical formula 4.

$${α}_{m} = \frac{1}{2 L} ln ( \frac{1}{{R}_{f} \cdot {R}_{r}} ) \qquad [ Mathematical formula 4 ]$$

Differential efficiency η_{f} of light generated from the active layer 15 is expressed by Mathematical formula 5.

$${η}_{f} = {η}_{d} \{ \frac{1}{1 + \sqrt{\frac{{R}_{f}}{{R}_{r}} ( \frac{1 - {R}_{r}}{1 - {R}_{f}} )}} \} \qquad [ Mathematical formula 5 ]$$

Further, from the empirical equation, a threshold Iₜₕ (T) depending on temperatures is expressed as Mathematical formula 6, and a differential efficiency η_{d} (T) depending on temperatures is expressed as Mathematical formula 7:

$${I}_{th} ( T ) = {I}_{th} ( {T}_{c} ) exp ( \frac{T - {T}_{c}}{{T}_{o}} ) \qquad [ Mathematical formula 6 ]$$

[Mathematical Formula 7]
η_{d}(T)=η_{d}(0° C.)−kₜ·T²
where since the red material is used in this embodiment, the value in the range of Tₒ=50 K to 100 K, and the value in the range of kₜ=5×10⁻⁻⁵ are respectively substituted. Thereby, the front light output P_{f} is obtained as Mathematical formula 8.

[Mathematical Formula 8]
P_{f}(Tₒ)=η_{f}(T){Iₒₚ−Iₜₕ(T)}

Next, in order to evaluate heat generation and temperature rise of the laser diode 10, the serial resistance Rₛ in the device is obtained by Mathematical formula 9, and the hest resistance Rₜₕ is obtained by Mathematical formula 10:

$${R}_{s} = \frac{{r}_{s} \cdot {d}_{c}}{L \cdot W} \qquad [ Mathematical formula 9 ]$$

$${R}_{th} = \frac{{r}_{th} \cdot {d}_{c}}{L \cdot {W}^{ 0.7}} \qquad [ Mathematical formula 10 ]$$

where rₛ is a serial resistance in the device per unit resonator length, unit stripe width, and unit cladding layer thickness; and rth is a heat resistance per unit resonator length, unit stripe width, and unit cladding layer thickness. Thereby, a heat value H is obtained as Mathematical formula 11 (dependence of d_{c} and W in αᵢ was ignored):

[Mathematical formula 11]
H=Rₛ·Iₒₚ²+(1−ηₐ)·Iₜₕ·Vₜₕ+ηₐ·η_{b}·Iₜₕ·Vₜₕ
where the first term represents heat generation by the resistance in the device, the second term represents heat generation by non-light emitting recombination until the threshold value, and the third term represents reabsorbed heat from the spontaneously emitted heat. ηₐ represents a spontaneous emission probability, and η_{b} represents a reabsorption probability from spontaneously emitted heat. In calculation, ηₐ=90% and η_{b}=50% were used.

Further, the light output P_{f} and a light emitting efficiency K_{f} were obtained by repeating the following procedure:
1) Ith is obtained by Mathematical formulas 1 and 2, and η_{f} is obtained by Mathematical formulas 3, 4, and 5. The obtained results are Iₜₕ⁰ and η_{f}⁰, respectively.
2) H is obtained by Mathematical formula 11, where Iₒₚ=Iₜₕ⁰+ΔI (ΔI is arbitrarily selected).
3) The temperature rise is calculated by ΔT=RₜₕH to obtain a temperature of the laser diode 10, T (=ΔT+Tₛ).
4) The threshold Iₜₕ (T) is obtained by Mathematical formula 6, and the differential efficiency η_{d} (T) is obtained by Mathematical formula 7.
5) P_{f} is obtained by Mathematical formula 8.
6) The light emitting efficiency K_{f} is obtained by Mathematical formula 12.

$${K}_{f} = \frac{{P}_{f}}{{I}_{op} \cdot {V}_{op}} \qquad [ Mathematical formula 12 ]$$
where Vₒₚ=Vₜₕ+Rₛ·Iₒₚ.

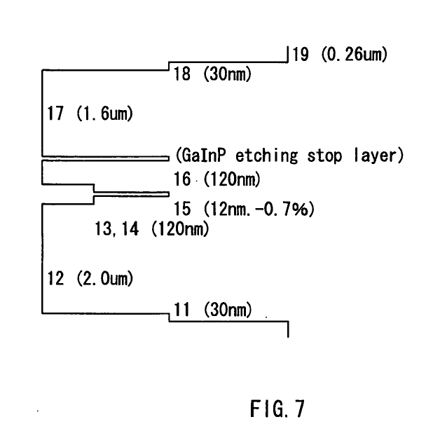

Further, Γ was separately obtained by guiding mode calculation. Then, the fundamental vertical structure of the laser diode shown in FIG. 7 was used as a model. Obtained values of the thickness of the active layer dₐ and the confinement factor Γ are shown in Table 1.

TABLE 1

| Thickness dₐ of active layer 15 | |
|---|---|
| (μm) | Confinement factor Γ |
| 60 | 0.020983 |
| 65 | 0.022777 |
| 70 | 0.024578 |
| 75 | 0.026385 |
| 80 | 0.0282 |
| 85 | 0.03002 |
| 90 | 0.031848 |
| 95 | 0.033682 |
| 100 | 0.035522 |
| 105 | 0.037369 |
| 110 | 0.039222 |
| 115 | 0.041081 |
| 120 | 0.042946 |
| 125 | 0.044818 |
| 130 | 0.046696 |
| 135 | 0.04858 |
| 140 | 0.050469 |
| 145 | 0.052365 |
| 150 | 0.054267 |
| 155 | 0.056174 |
| 160 | 0.058088 |
| 165 | 0.060007 |
| 170 | 0.061932 |
| 175 | 0.063862 |
| 180 | 0.065798 |

First, by fitting the calculation results to the representative experimental results, values of main parameters, on which the calculation is based (the internal quantum efficiency ηᵢ and the waveguide loss αᵢ of Mathematical formula 3) were determined, and then subsequent calculation was implemented. Experimental data used for fitting the parameters was dependence of the front end face reflectance R_{f} of the external differential quantum efficiency η_{d}. When fitting was tried by using the data where L is 1400 μm with little influence of internal heat generation, matching was well made where αᵢ was 2.5 cm⁻¹ and ηᵢ was 0.7. Therefore, for confirmation, when these values were approximated from experimental values on dependence of the resonator length L of 1/η_{d} by using Mathematical formulas 3, 4, and 5, results were αᵢ≈1.4 cm⁻¹ and ηᵢ≈0.6. Though affected by heat, such values were close to the foregoing fitted values. Therefore, the foregoing values were used. In view of the foregoing results, where L was 1400 μm or L was 700 μm, d was 120 A, Γ was 0.0429, αᵢ was 2.5 cm⁻¹, R_{f} was 5% to 20%, Rᵣ was 90%, W was 60 μm, Jₒ was 4000 A/cm², Jᵢ was 90 A/cm², B was 0.023, dc was 2 μm, Rₛ was 0.47 Ω, Rₜₕ was 15.7 deg C./W, To was 70 K (50K where L was 700 μm), kt was 0.0001 deg C.⁻², and ηᵢ was 0.7.

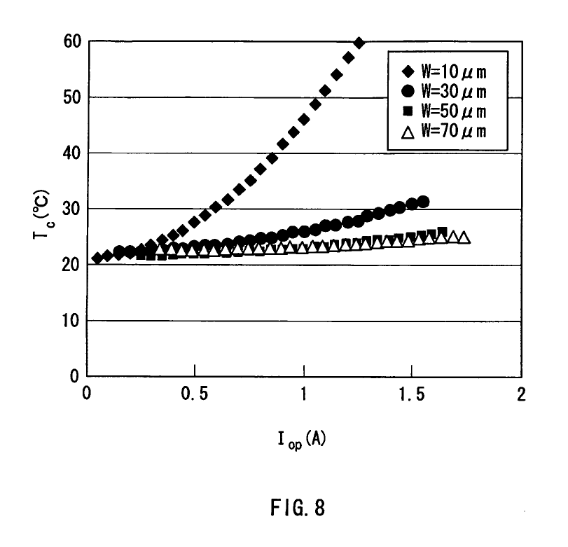

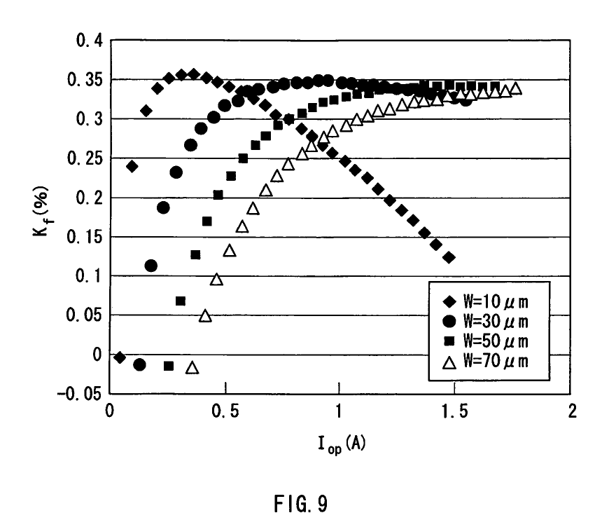

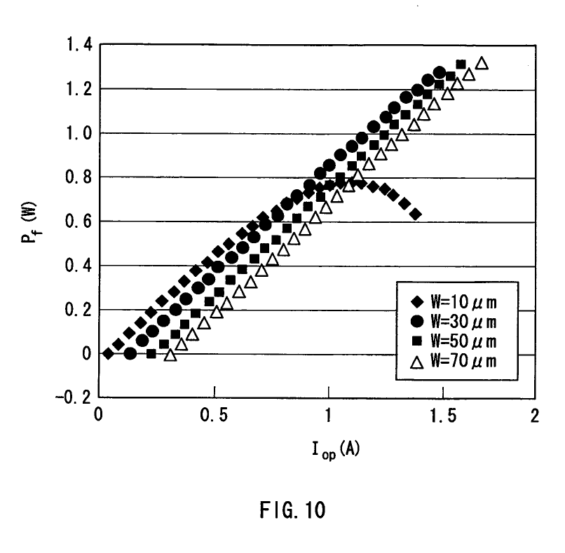

FIG. 8 shows relations between the the heat sink temperatures Tc and the drive currents Iₒₚ regarding laser diodes respectively fabricated with the resonator length L of 1400 μm and the stripe widths W of 10, 30, 50, and 70 μm. From these results, it is found that when the stripe width W is widened, to a certain width, heat generation is inhibited and exhaust heat is effectively performed so that it is advantageous to obtain high output. However, when the certain width is surpassed, the total heat value is increased, and the stripe width W is limited by the allowable heat of the laser diode 10. In view of the light emitting efficiency K_{f} shown in FIG. 9 and the light output P_{f} shown in FIG. 10, the narrower stripe width W is rather advantageous, in particular, is more advantageous in low output operation, since the narrower the stripe width W is, the lower the threshold is. Considering the foregoing, in the red band, the stripe width W is preferably 10 μm or more, and is more preferably 50 μm to 100 μm. When the resonator length L was 700 μm, similar trend was shown.

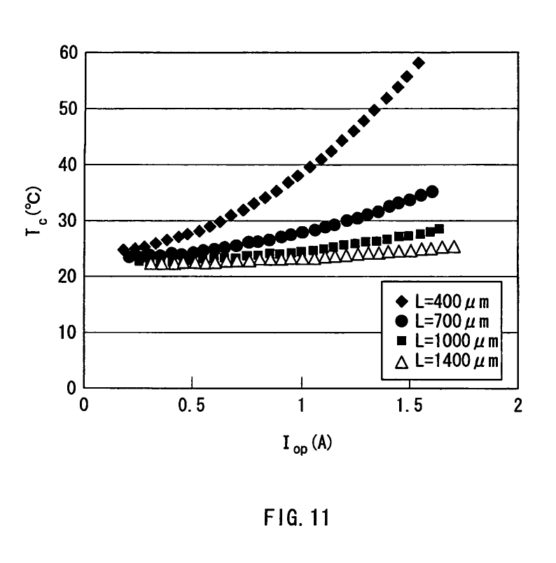

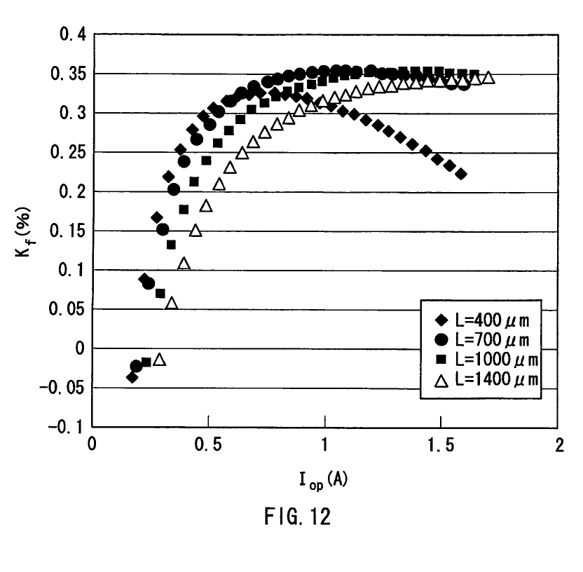

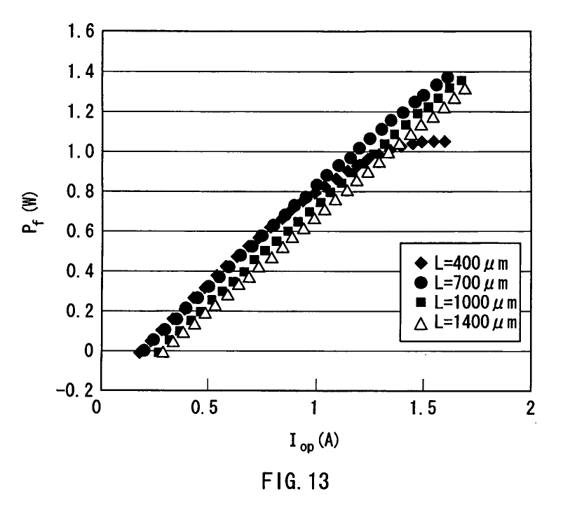

FIG. 11 shows relations between the heat sink temperatures Tc and the drive currents Iₒₚ regarding laser diodes respectively fabricated with the stripe width W of 60 μm and the resonator lengths L of 400, 700, 1000, and 1400 μm. According to the figure, it is found that when the resonator length L is lengthened, it becomes effective to obtain high output since it is advantageous in view of both heat generation and exhaust heat. However, in this case, the total heat value is increased. In view of the light emitting efficiency K_{f} shown in FIG. 12 and the light output P_{f} shown in FIG. 13, different from the case widening the stripe width W, the threshold is not much increased when the resonator length L is lengthened. The reason thereof is as follows. Though the medium to be excited (volume of the active layer) is increased by lengthening the resonator length L, the ratio per unit length to the loss on the end face is decreased. That is, even if the resonator length L is lengthened, it is not as disadvantageous as in the case of lengthening the stripe width W. On the contrary, when the resonator length L is too shortened, it becomes disadvantageous. Selection may be made according to the practical output value from around the range from L=700 μm to L=1400 μm. Specifically, in the case of about W=60 μm, L=700 μm is preferable for 0.8 W class, and L=1400 μm is preferable for 1.4 W class. Further, respective values of the front end face reflectance R_{f} suitable for these resonator lengths L exist.

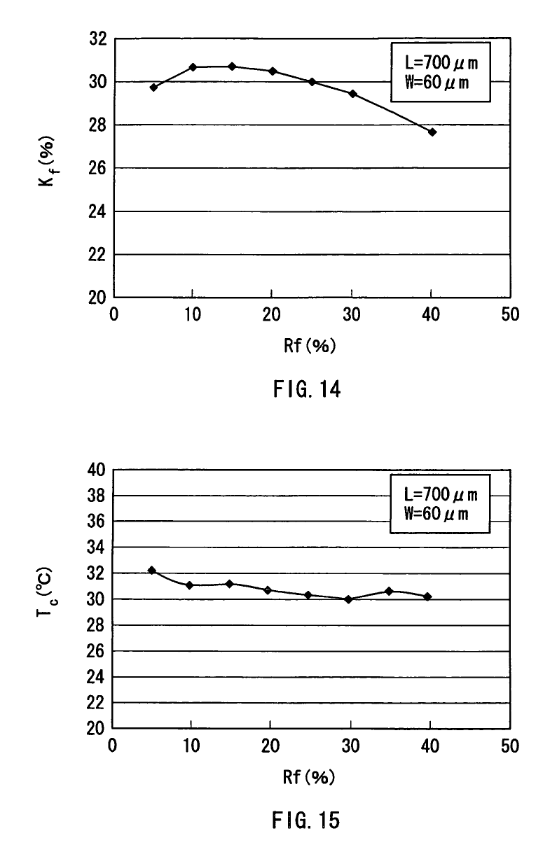

Regarding the case, in which the resonator length L was 700 μm (700 μm≦L≦1000 μm) and the stripe width W was 60 μm (10 μm≦W), a relation between the front end face reflectance R_{f} and the light emitting efficiency K_{f} is shown in FIG. 14, and a relation between the front end face reflectance R_{f} and the heat sink temperatures T_{c} is shown in FIG. 15. From these figures, it is found that the front end face reflectance R_{f} is preferably 10% to 30%.

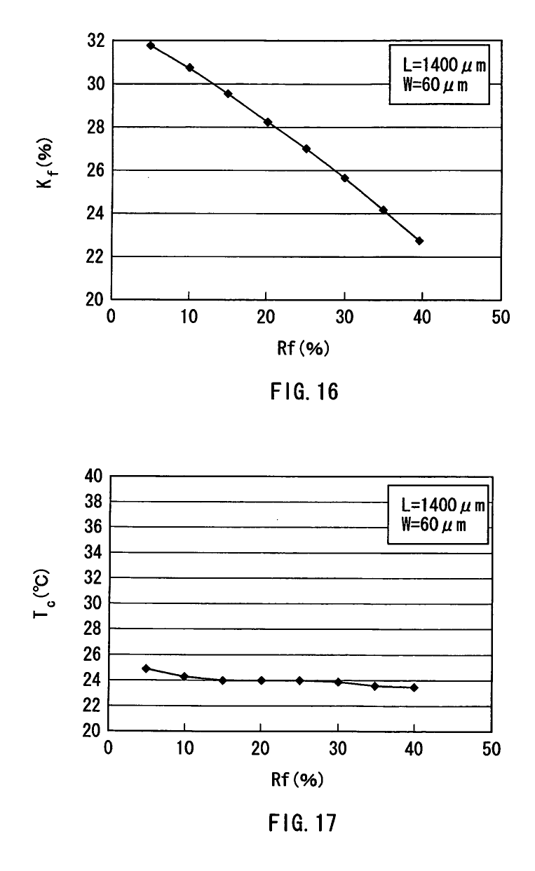

Further, regarding the case, in which the resonator length L was 1400 μm (1000 μm≦L) and the stripe width W was 60 μm (10 μm≦W), a relation between the front end face reflectance R_{f} and the light emitting efficiency K_{f} is shown in FIG. 16, and a relation between the front end face reflectance R_{f} and the heat sink temperatures T_{c} is shown in FIG. 17. From these figures, it is found that the front end face reflectance R_{f} is preferably 2% to 15%.

Meanwhile, in either resonator length, it was confirmed that the rear end face reflectance Rᵣ was preferably 90% or more, and the rear end face reflectance Rᵣ closer to 100% was more preferable.

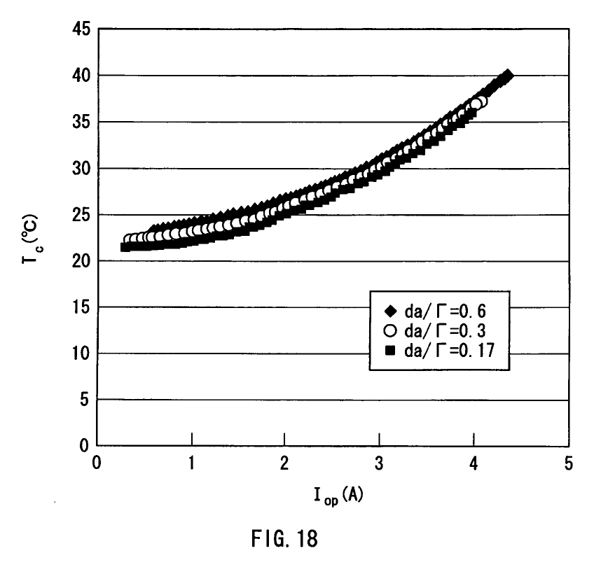

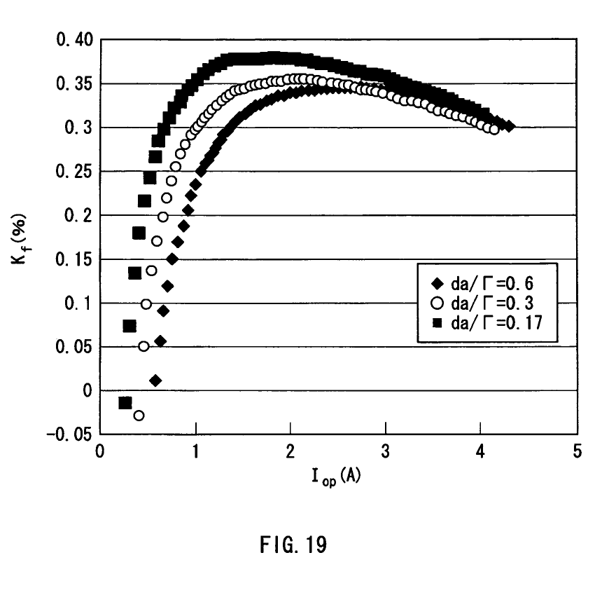

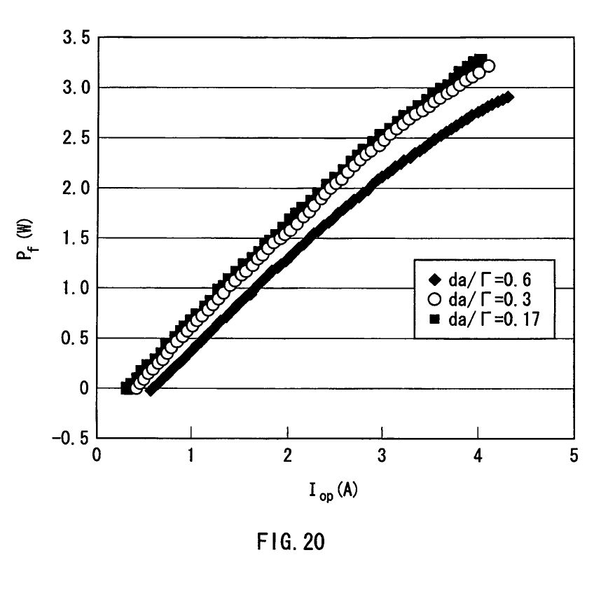

Further, the value of dₐ/Γ, showing how wide the width in the vertical direction to confine energy of the light guiding mode is, and meaning that the larger the value is, the wider the light guiding mode is was obtained. In the case of the resonator length L=700 μm, the stripe width W=60 μm, the front end face reflectance R_{f}=15%, the thickness of the p-type cladding layer d_{c}=0.7 μm, and dₐ/Γ=0.6, 0.3, and 0.17, relations between the drive currents Iₒₚ and the heat sink temperatures T_{c} are shown in FIG. 18, relations between the drive currents Iₒₚ and the light emitting efficiency K_{f} are shown in FIG. 19, relations between the drive currents Iₒₚ and the light output P_{f} are shown in FIG. 20. From these figures, it is found that in the case of the laser diode having a stripe width of 10 μm or more and a resonator length of 700 μm or more, the value of dₐ/Γ is preferably 0.3 μm or less. In this range, the light guiding mode moderately concentrates on the active layer 15, the threshold of the drive current Iₒₚ is decreased, and the light loss (C₁ section in FIG. 3) is not increased even if the thin p-type cladding layer 17 is used as described in the first embodiment. Thereby, the light emitting output and the light emitting efficiency are improved, the temperature rise of the laser diode 10 is inhibited, and 35% or more light emitting efficiency can be obtained based on calculation. When Γ is enormously increased, that is, when the optical density in the active layer 15 is increased too much, the end face destruction level is decreased. Therefore, increase in Γ has the upper limit. However, in the case of the broad area type laser having a stripe width W of 10 μm or more as the laser diode in this embodiment, light is broadened in the horizontal direction as well. Therefore, the upper limit of Γ can be set high.

The heat sink 24 is made of a material having thermal and electrical conductivity such as copper (Cu). Thermal conductivity is necessary characteristics for emitting heat generated particularly from the p-type cladding layer 17 and maintaining appropriate temperatures of the laser diode 10. Electrical conductivity is necessary characteristics for effectively conducting a current to the laser diode 10.

The sub-mount 25 is made of, for example, silicon carbide (SiC), aluminum nitride (AlN), or copper tungsten (WCu). The sub-mount 25 is intended to make exhaust heat more effectively.

The solder layer 26 is preferably made of lead (Pb)-free solder such as tin-silver-copper (Sn—Ag—Cu) solder and tin-zinc (Sn—Zn) solder, in order to reduce environmental load. Further, it is preferable to weld the laser diode 10 and the sub-mount 25 with the solder layer 26, which is made as thin as possible. When the layer thickness of the solder layer 26 is thickened, the exhaust heat efficiency is decreased.

The laser diode 10 can be manufactured as follows.

First, as in the first embodiment, the laser diode 10 is fabricated. Then, the light emitting region 15A is formed so that the stripe width W becomes 10 μm or more. Further, the rear end face 15C is formed by using a 90% or more reflector film. When the laser diode 10 is formed with the resonator length L of 700 μm to 1000 μm, the front end face 15B is formed by using a 10% to 30% reflector film. When the laser diode 10 is formed with the resonator length L of 1000 μm or more, the front end face 15B is formed by using 2% to 15% reflector film.

Subsequently, the sub-mount 25 made of the foregoing material and the laser diode 10 are fixed by heated solder and the solder layer 26 is concurrently formed. Then, it is preferable that the p polarity side of the laser diode 10 and the sub-mount 25 are jointed, since exhaust heat efficiency can be improved by exhausting heat without through the layers on the n polarity side. Further, the sub-mount 25 and the heat sink 24 are jointed by using unshown silver paste or heated solder, and thereby the laser diode 10 integrated with the heat sink 24 shown in FIG. 6 is completed.

In the laser diode 10, when a given voltage is applied between the n-side electrode 22 and the p-side electrode 23, current confinement is made by the ridge 21, a current is injected into the active layer 15, and light is emitted by electron-hole recombination. The light is reflected by an unshown pair of reflector films, travels between them, generates laser oscillation, and is emitted outside as a laser beam.

Here, the p-type cladding layer 17 is formed thinner than ever before, being 0.7 μm or less. In addition, appropriate ranges of the front end face reflectance R_{f} and the rear end face reflectance Rᵣ, and the relation between the confinement factor Γ of the light guiding mode in the active layer 15 and the thickness dₐ of the active layer 15 (dₐ/Γ) are respectively specified correspondingly to the stripe width W and the resonator length L. Therefore, actions as in the first embodiment can be obtained, and high output and high efficiency can be obtained.

As above, in the laser diode 10 of this embodiment, the p-type cladding layer 17 is formed thinner than ever before, being 0.7 μm or less. In addition, appropriate ranges of the front end face reflectance R_{f} and the rear end face reflectance Rᵣ, and the relation between the confinement factor Γ of the light guiding mode and the thickness dₐ of the active layer 15 (dₐ/Γ) are respectively specified correspondingly to the stripe width W and the resonator length L. Therefore, actions as in the first embodiment can be obtained, and high output and high efficiency can be obtained. Consequently, temperature characteristics and light emitting efficiency can be improved, and reliability can be improved.

In particular, in the case that the resonator length L is 700 μm to 1000 μm, when the front end face reflectance R_{f} is 10% to 30%, and the rear end face reflectance Rᵣ is 90% or more, higher effects can be obtained.

Further, in the case that the resonator length L is 1000 μm or more, when the front end face reflectance R_{f} is 2% to 15%, and the rear end face reflectance Rᵣ is 90% or more, higher effects can be obtained.

Further, when the relation between the confinement factor r of the light guiding mode and the thickness dₐ of the active layer is dₐ/Γ≦0.3 μm, higher effects can be obtained.

Further, specific effects will be hereinafter shown.

In the case of shortening a wavelength to 640 nm or less, stable operation at high temperatures also becomes enabled, and red practical wavelength limit for the laser diode 10 can be further expanded to 630 nm or less.

It becomes possible to obtain high output up to about 300 mW. For example, the laser diode can be used as a laser for writing in order to speed up the DVD drive. Further, since temperature characteristics and reliability are improved, the laser diode can be applied to the DVD drive for automobile use. Thereby, high yield and low cost of DVD products can be obtained. Further, in the case of using the laser diode as a dual wavelength laser integrated with the laser for CD, laser characteristics and yield can be improved, and low cost can be further obtained.

Further, the red laser diode having a W (watt) class high output, a broad wavelength range, 30% or more light emitting efficiency under operation temperatures of 30 deg C. or more and the like, which are demanded characteristics in the fields of optical disk apparatuses, display apparatuses, laser beam machines, medical equipment and the like can be put to practical use.

The foregoing laser diode 10 can be applied to various devices such as optical disk apparatuses and display apparatuses. One example thereof will be hereinafter described.

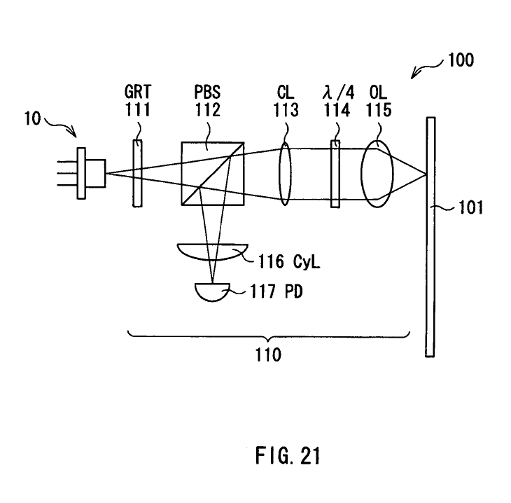

FIG. 21 schematically shows an example of a configuration of an optical apparatus including the foregoing laser diode 10. An optical apparatus 100 is used as an optical pickup for high density recording and reproducing by a DVD or the like. The optical apparatus 100 includes the laser diode 10 as a light source, an optical system 110 provided between the laser diode 10 and a recording medium 101 such as a DVD. On the surface of the recording medium 101, lots of pits (projections) being several μm in size are formed. The optical system 110 is arranged in the light path from the laser diode 10 to the recording medium 101. For example, the optical system 110 has a grating 111, a polarizing beam splitter 112, a parallel lens 113, a quarter-wavelength plate 114, an object lens 115, a cylindrical lens 116, and a light receiving device 117 such as a photodiode.

In the optical apparatus 100, light from the light source (laser diode 10) passes through the grating 111, the polarizing beam splitter 112, the parallel lens 113, the quarter-wavelength plate 114, and the object lens 115, focuses on the recording medium 101, and is reflected by the pits on the surface of the recording medium 101. The reflected light passes through the object lens 115, the quarter-wavelength plate 114, the parallel lens 113, the polarizing beam splitter 112, and the cylindrical lens 116 to enter the light receiving device 117. Then, a pit signal, a tracking signal, and a focus signal are read.

As above, in the optical apparatus 100 according to this embodiment, the laser diode 10 of the foregoing embodiment is used as a light source. Therefore, the temperature characteristics and reliability are high, and stable usage is enabled in a wide temperature range. The optical apparatus 100 is not limited to the reproduction only optical apparatus, but may be the optical disk apparatus capable of recording and reproducing.

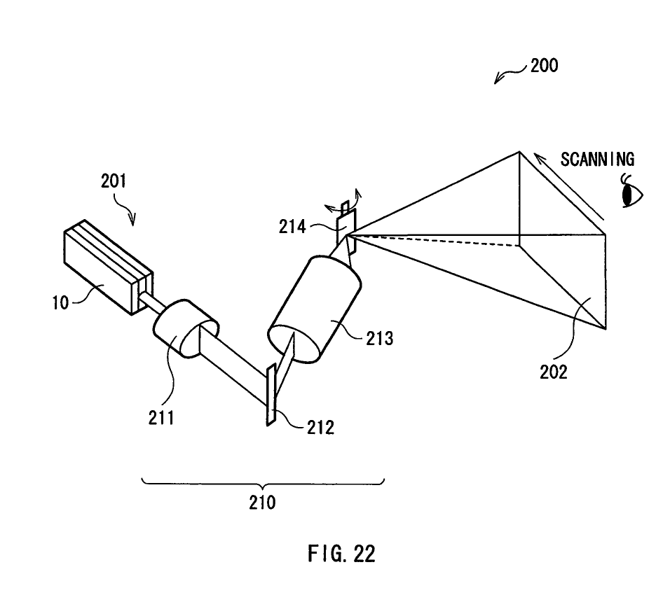

Further, as other optical apparatus including the foregoing laser diode 10, FIG. 22 schematically shows an example of a configuration of a display apparatus 200. The display apparatus 200 is a laser display, in which the laser diode 10 is used as a red light source. For example, the display apparatus 200 includes a light source 201 including the laser diode 10, and an optical system 210 provided between the light source 201 and a screen 202. The optical system 210 is provided in a light path from the light source 201 to the screen 202. For example, the optical system 210 has a lighting lens 211, a laser display 212, a projection lens 213, and a scanning mirror 214.

In the display apparatus 200, light from the light source 201 (laser diode 10) passes through the lighting lens 211, the laser display 212, the projection lens 213, and the scanning mirror 214 to focus on the screen 202. For example, images are displayed by scanning sequentially from upper left of the screen 202 from the viewpoint of the viewer side.

As above, the display apparatus 200 in this embodiment includes the laser diode 10 in the foregoing embodiment having high color purity as a red light source of the light source 201. Therefore, color reproducibility twice as of the CRT method can be realized. In addition, the temperature characteristics and reliability are high, and therefore stable usage is enabled in a wide temperature range.

Descriptions have been hereinbefore given of the present invention with reference to the embodiments. However, the present invention is not limited to the foregoing embodiments, and various modifications may be made. For example, the material, the deposition method, and the deposition conditions for the respective layers described in the foregoing embodiments are not limited, but other material, other deposition method, and other deposition conditions may be used.

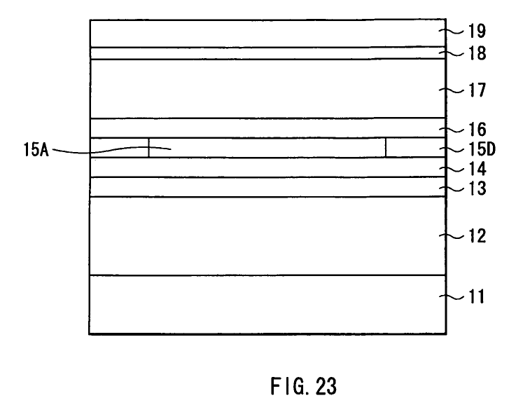

Further, for example, in the foregoing embodiments, current confinement is made by forming the buried layer (refer to FIG. 2). However, as shown in FIG. 23, it is possible to make current confinement by oxidizing the outer edge of the active layer to form an insulating layer 15D and applying a current to the central portion of the active layer.

Furthermore, in the first and the second embodiments, the case that the laser diode having a resonator length of 1400 μm or less is integrated with the heat sink has been described. However, in the case of using a heat sink, it is preferable to form the laser diode having a resonator length of about 2 μm or less, since it is difficult to obtain a 2 μm or more heat sink as a general purpose product.

In addition, for example, in the foregoing embodiments, the constructions of the laser diode have been described with reference to the specific examples. However, it is not necessary to provide all layers, or other layer such as a buffer layer may be further provided.

The laser diode 10 according to the embodiments of the present invention can be applied to optical disks, display apparatuses, laser equipment for process, medical equipment, and the like.

(Stylized Paragraph)

It should be understood by those skilled in the art that various modifications, combinations, sub-combinations and alternations may occur depending on design requirements and other factors insofar as they are within the scope of the appended claims or the equivalents thereof.

What is claimed is:

1. A laser diode at least comprising:
an n-type cladding layer;
an active layer; and
a p-type cladding layer, which are made of an AlGaInP compound semiconductor material and formed in this order on a substrate,
wherein a thickness of the p-type cladding layer is 0.7 μm or less.

2. A laser diode according to claim 1, wherein the p-type cladding layer has +strain, and the average crystal lattice mismatch degree Δa/a to the substrate is +3×10⁻³ or more (Δa represents a difference between a crystal lattice constant of the p-type cladding layer and a crystal lattice constant of the substrate; and a represents a crystal lattice constant of the substrate).

3. A laser diode according to claim 2, wherein a concentration of p-type impurity in the p-type cladding layer is 2×10¹⁸/cm³ to 3×10¹⁸/cm³.

4. A laser diode according to claim 3, wherein the p-type impurity contains at least one of zinc and magnesium.

5. A laser diode according to claim 1 comprising:
an n-type guiding layer including one or more layers between the active layer and the n-type cladding layer; and
a p-type guiding layer including one or more layers between the active layer and the p-type cladding layer,
wherein the layer number of the n-type guiding layer is larger than the layer number of the p-type guiding layer.

6. A laser diode according to claim 1 comprising:
an n-type guiding layer between the active layer and the n-type cladding layer; and
a p-type guiding layer between the active layer and the p-type cladding layer,
wherein a thickness of the n-type guiding layer is thicker than a thickness of the p-type guiding layer.

7. A laser diode according to claim 1 comprising:
an n-type guiding layer between the active layer and the n-type cladding layer; and
a p-type guiding layer between the active layer and the p-type cladding layer,
wherein a refractive index of the n-type guiding layer is larger than a refractive index of the p-type guiding layer.

8. A laser diode at least comprising:
an n-type cladding layer;
an active layer; and
a p-type cladding layer, which are made of an AlGaInP compound semiconductor material and formed in this order on a substrate,
wherein a thickness of the p-type cladding layer is 0.7 μm or less, a stripe width in a light emitting region in the active layer is 10 μm or more, and a resonator length is 700 μm or more.

9. A laser diode according to claim 8, wherein the resonator length is 700 μm to 1000 μm, reflectance on a front end face is 10% to 30%, and reflectance on a rear end face is 90% or more.

10. A laser diode according to claim 8, wherein the resonator length is 1000 μm or more, reflectance on a front end face is 2% to 15%, and reflectance on a rear end face is 90% or more.

11. A laser diode according to claim 8, wherein a thickness d of the active layer with respect to a light guiding mode confinement factor Γ to the active layer is expressed as d/Γ≦0.3 μm.

12. An optical apparatus comprising:
a laser diode,
wherein the laser diode at least includes an n-type cladding layer, an active layer, and a p-type cladding layer, which are made of an AlGaInP compound semiconductor material and formed in this order on a substrate, and a thickness of the p-type cladding layer is 0.7 μm or less.

13. An optical apparatus comprising:
a laser diode,
wherein the laser diode at least includes an n-type cladding layer, an active layer, and a p-type cladding layer, which are made of an AlGaInP compound semiconductor material and formed in this order on a substrate, a thickness of the p-type cladding layer is 0.7 μm or less, a stripe width in a light emitting region in the active layer is 10 μm or more, and a resonator length is 700 μm or more.
